(19) United States
(12) Patent Application Publication
(10) Pub. No.: US 2007/0096286 A1
(43) Pub. Date: May 3, 2007

(54) Semiconductor module capable of enlarging stand-off height

(75) Inventor: Shigekazu Hino, Sakai-shi (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/541,668

(22) Filed: Oct. 3, 2006

(30) Foreign Application Priority Data
Oct. 27, 2005 (JP) 2005-312181

(51) Int. Cl. H01L 23/02

(52) U.S. Cl. 257/686

(57) ABSTRACT

In a semiconductor module including a first connection substrate having first and second surfaces opposite to each other, and at least one first semiconductor device mounted on the first surface of the first connection substrate, a second connection substrate having at least one opening is adhered to the second surface of the first connection substrate. At least one second semiconductor device is mounted on the second surface of the first connection substrate through the opening of the second connection substrate, and external electrodes are formed on a surface of the second connection substrate opposite to the first connection substrate.

### BACKGROUND OF THE INVENTION

1. Field of the Invention

The present invention relates to a semiconductor module such as a chip size package (CSP) module.

2. Description of the Related Art

Recently, electronic apparatuses have become smaller and thinner in size, to satisfy the need for high density package modules.

As high density package modules, CSP modules using ball grid arrays (BGAs) have been known.

A prior art CSP semiconductor module is constructed by a single connection substrate (interposer substrate) having a front surface and a back surface. One or more semiconductor chips are mounted on the front surface and external electrodes are formed on the back surface. The pins (pads) of the semiconductor chips are electrically connected via interconnects within the single connection substrate to the external electrodes. In this case, since the spacing between the pins (pad) of the semiconductor chips is extended by the connection substrate to the spacing of the external electrodes, the semiconductor module can easily be mounted on a wiring printed board or a mother board (see: FIG. 5 of JP-2002-270762 A). This will be explained later in detail.

In the above-described first prior art semiconductor module, however, since the semiconductor chips are mounted only on the front surface of the connection substrate, the packaging density of semiconductor chips is very low.

In a second prior art CSP semiconductor module, semiconductor chips are mounted on both of the front and back surfaces, so that the packaging density of semiconductor chips can be increased (see: FIGS. 1 and 3 of JP-2002-270762 A). This also will be explained later in detail.

### SUMMARY OF THE INVENTION

In the above-described second prior art semiconductor module, however, the following problems occur. First, since the semiconductor chips mounted on the back surface of the connection substrate need to be within a stand-off height defined by the external electrodes, there is a limit of thickness in such semiconductor chips. Secondly, if the stand-off height is increased to increase the thickness of such semiconductor chips, the width of the external electrodes is also increased, to thereby decrease the density of the external electrodes, which would not increase the number of mounted semiconductor chips. Finally, if the width of the external electrodes is increased, it is difficult to form fine connections on the back surface of the connection substrate. In this case, one interconnect layer within the connection substrate serves as such fine connections, so that the density of interconnect layers within the connection substrate is also increased, to thereby increase the manufacturing cost.

According to the present invention, in a semiconductor module including a first connection substrate having first and second surfaces opposite to each other, and at least one first semiconductor device mounted on the first surface of the first connection substrate, a second connection substrate having at least one opening is adhered to the second surface of the first connection substrate. At least one second semiconductor device is mounted on the second surface of the first connection substrate through the opening of the second connection substrate, and external electrodes are formed on a surface of the second connection substrate opposite to the first connection substrate.

Since a stand-off height is defined by the second connection substrate and the external electrodes, the stand-off height can be enlarged by arbitrarily changing the thickness of the second connection substrate. As a result, there is no substantial limit in thickness of the second semiconductor device. Also, since fine connections can easily be formed on one of the surfaces of the first connection substrate opposing the second connection substrate, the density of interconnect layers within the first connection substrate can be substantially decreased, which would decrease the manufacturing cost. Further, since a part of interconnects with the first connection substrate can be moved to the second connection substrate, the density of interconnects with the first connection substrate can be decreased, which also would decrease the manufacturing cost.

### BRIEF DESCRIPTION OF THE DRAWINGS

The present invention will be more clearly understood from the description set forth below, as compared with the prior art, with reference to the accompanying drawings, wherein:

FIG. 1A is a cross-sectional view illustrating a first prior art semiconductor module;

FIG. 1B is a back view of the semiconductor module of FIG. 1A;

FIG. 2A is a cross-sectional view illustrating a second prior art semiconductor module;

FIG. 2B is a back view of the semiconductor module of FIG. 2A;

FIG. 3A is a cross-sectional view illustrating a first embodiment of the semiconductor module according to the present invention;

FIG. 3B is a back view of the semiconductor module of FIG. 3A;

FIG. 4A is a cross-sectional view illustrating a second embodiment of the semiconductor module according to the present invention; and

FIG. 4B is a back view of the semiconductor module of FIG. 4A.

### DESCRIPTION OF THE PREFERRED EMBODIMENTS

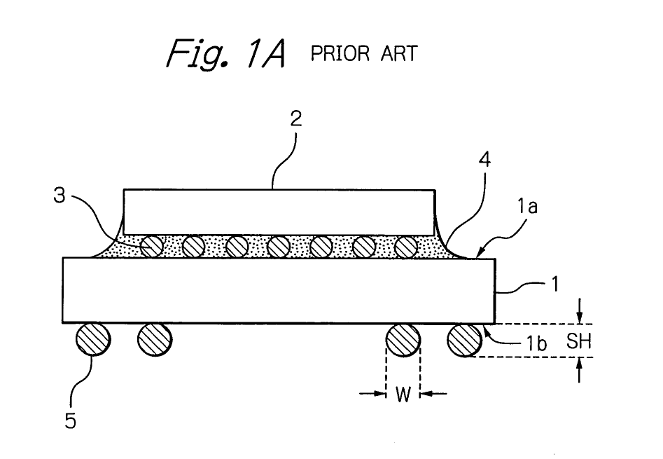

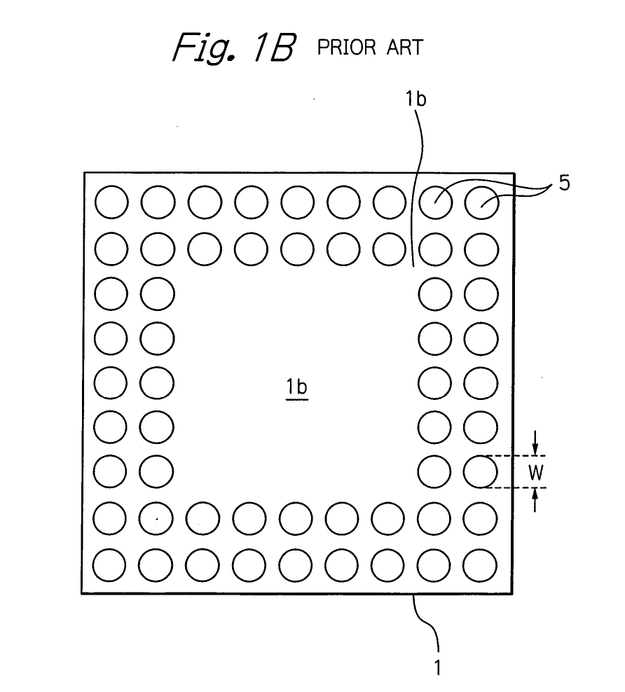

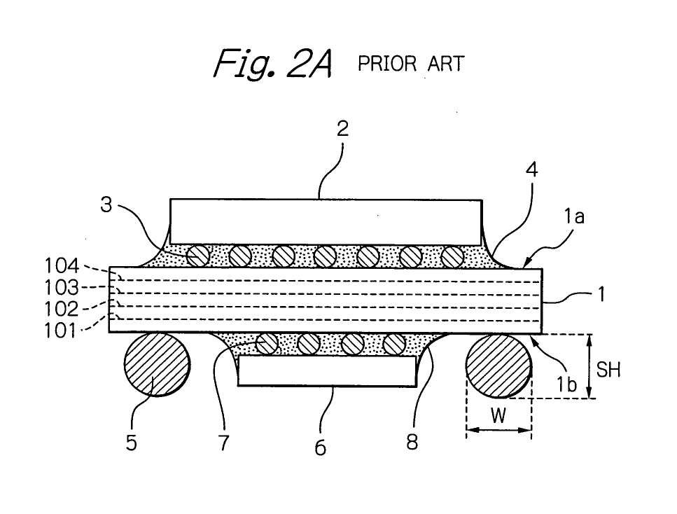

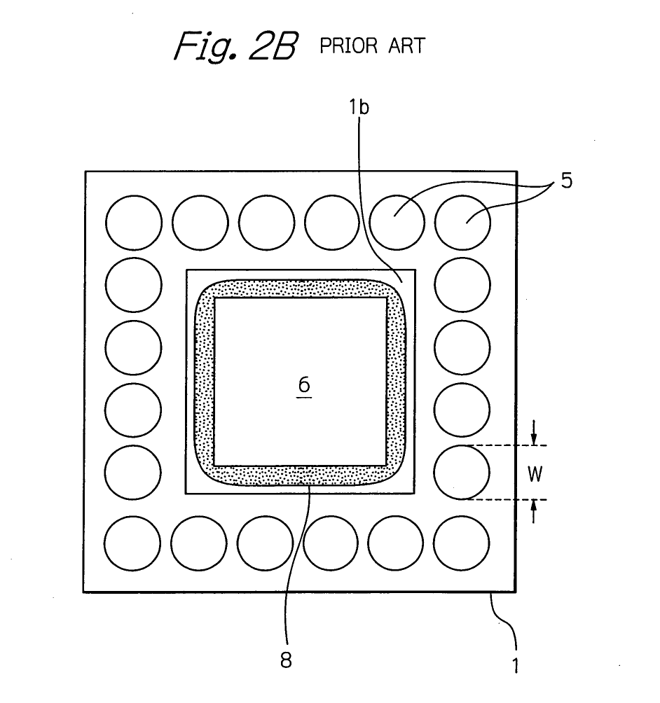

Before the description of the preferred embodiments, prior art semiconductor modules will be explained with reference to FIGS. 1A, 1B, 2A and 2B.

In FIGS. 1A and 1B, which illustrate a first prior art semiconductor module (see: FIG. 5 of JP-2002-270762 A), a chip size package (CSP) module is constructed by a connection substrate (interposer substrate) 1 with a front surface 1a and a back surface 1b. Also, a semiconductor chip 2 having protruded electrodes 3 such as solder balls plated bumps or stad bumps on the surface electrodes thereof is faced down to the front surface 1a of the connection substrate 1 by a heating and/or pressing process, so that the protruded electrodes 3 of the semiconductor chip 2 are aligned with the electrodes (not shown) on the front surface la of the connection substrate 1. Also, the gap therebetween is sealed by an underfill resin layer 4. Further, the protruded electrodes 3 of the semiconductor 2 are connected via interconnects (not shown) of the connection substrate 1 to external electrodes 5 such as solder balls on the back surface of the connection substrate 1.

Thus, in the semiconductor module of FIGS. 1A and 1B, the size can be as small as that of the semiconductor chip 2. Also, since the width W of the external electrodes 5 can be small so that the stand-off height SH can be small, the height of the semiconductor module of FIGS. 1A and 1B can be small. Further, the spacing between the protruded electrodes 3 of the semiconductor chip 2 are extended by the connection substrate 1 to the spacing between the external electrodes 5 thereof while the width W of the external electrodes 5 is small, so that the semiconductor module of FIGS. 1A and 1B can easily be mounted on a wiring printed board or a mother board (not shown).

In the semiconductor module of FIGS. 1A and 1B, however, since one or more semiconductor chips are mounted only on the front surface 1a of the connection substrate 1, the packaging density of semiconductor chips is very low.

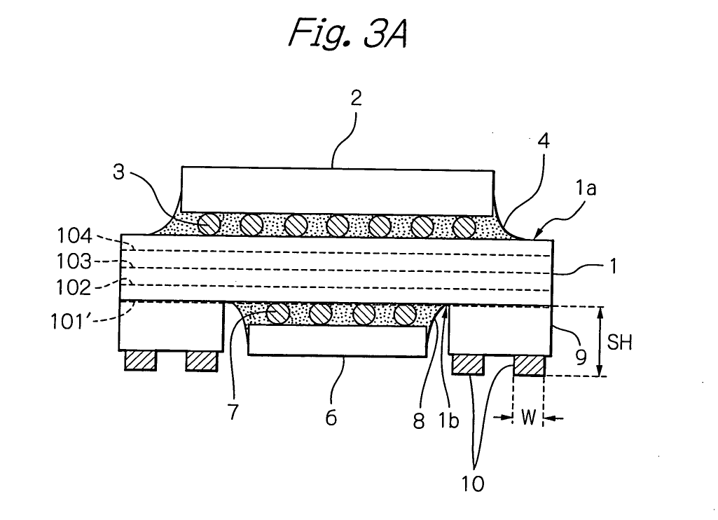

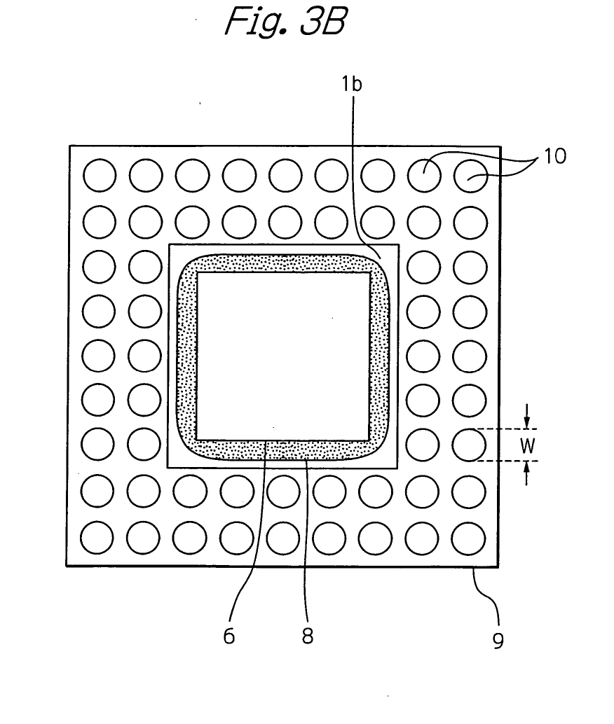

In FIGS. 2A and 2B, which illustrate a second prior art semiconductor module (see: FIGS. 1 and 3 of JP-2002-270762 A), another semiconductor chip 6 having protruded electrodes 7 such as solder balls, plated bumps or stad bumps on the surface electrodes thereof is faced down to the back surface 1b of the connection substrate 1 of FIGS. 1A and 1B by a heating and/or pressing process, so that the protruded electrodes 7 of the semiconductor chip 6 are aligned with the electrodes (not shown) on the back surface 1b of the connection substrate 1. Also, the gap therebetween is sealed by an underfill resin layer 8. Further, the protruded electrodes 7 of the semiconductor 6 are connected via interconnects (not shown) of the connection substrate 1 to external electrodes 5 such as solder balls on the back surface of the connection substrate 1.

Thus, in the semiconductor module of FIGS. 2A and 2B, since two or more semiconductor chips are mounted on both of the surfaces 1a and 1b of the connection substrate 1, the packaging density of semiconductor chips can be increased.

In the semiconductor module of FIGS. 2A and 2B, however, the following problems. First, since the semiconductor chips 6 associated with the protruded electrodes 7 need to be within a stand-off height SH defined by the external electrodes 5, there is a limit of thickness in such semiconductor chip 6. Secondly, if the stand-off height SH is increased to increase the thickness of the semiconductor chip 6, the width W of the external electrodes 5 is also increased, to thereby decrease the density of the external electrodes 5, which would not increase the number of mounted semiconductor chips. Finally, if the width W of the external electrodes 5 is increased, it is difficult to form fine connections on the back surface 1b of the connection substrate 1, since the large external electrodes 5 are obstacles to formation of such fine connections. In this case, one interconnect layer within the connection substrate 1 serves as such fine connections, so that the number of interconnect layers such as 101, 102, 103 and 104 is increased, the density of interconnect layers within the connection substrate 1 is also increased, to thereby increase the manufacturing cost.

In FIGS. 3A and 3B, which illustrate a first embodiment of the semiconductor module according to the present invention, a hollowed connection substrate (or interposer substrate) 9 associated with external plane electrodes 10 is provided instead of the external electrodes 5 of FIGS. 2A and 2B.

In FIGS. 3A and 3B, since a stand-off height SH is defined by the height of the connection substrate 9 plus the thickness of the external plane electrodes 10, so that the stand-off height SH can be arbitrarily set by the height of the connection substrate 9, there is no substantial limit of thickness in the semiconductor chip 6. That is, the stand-off height SH can be increased by increasing only the height of the connection substrate 9 while the thickness of the external electrodes 5 remains small. As a result, the width W of the external plane electrodes 10 remains small, so that the density of the external electrodes 10 can be maintained high, which would increase the number of mounted semiconductor chips. Also, since a fine connection layer 101′ can easily be formed on the back surface 1b of the connection substrate 1, the number of interconnect layers such as 102, 103 and 104 is decreased, the density of the interconnect layers within the connection substrate 1 can be substantially decreased, which would decrease the manufacturing cost.

In FIGS. 3A and 3B, since a part of the interconnects of the connection substrate 1 can be moved to the connection substrate 9, the density of interconnects within the connection substrate 1 can be decreased, which also would decrease the manufacturing cost.

In FIGS. 3A and 3B, the external plane electrodes 10 can be formed by land grid array (LGA)-type plane electrodes made of Cu or Cu/NiAu.

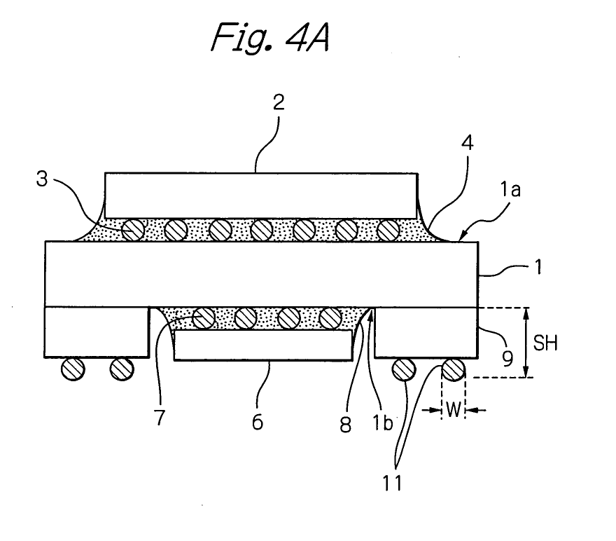

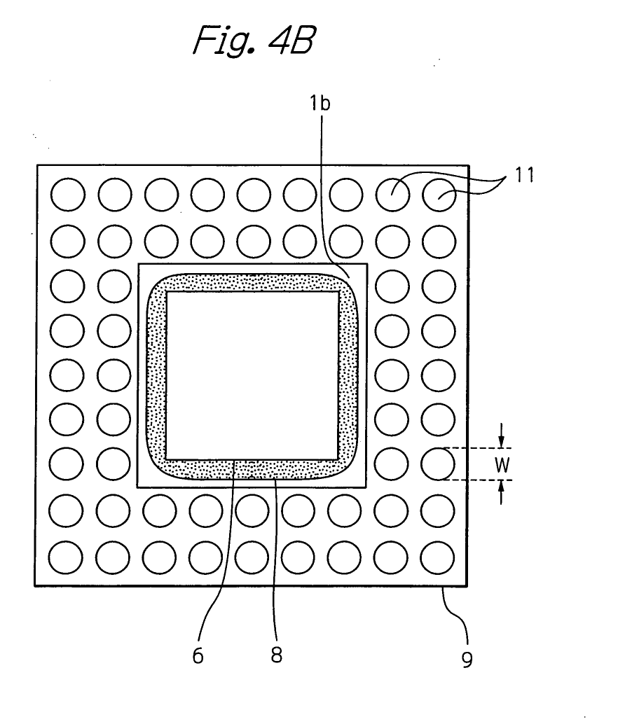

In FIGS. 4A and 4B, which illustrate a second embodiment of the semiconductor module according to the present invention, external protruded electrodes 11 such as solder balls, plated bumps or stad bumps are provided instead of the external plane electrodes 10 of FIGS. 3A and 3B. Since the height of the external protruded electrodes 11 can be larger than that of the external plane electrodes 10 of FIGS. 3A and 3B while the width W of the external protruded electrodes 11 is substantially the same as that of the external plane electrodes 10, the stand-off height SH can be larger, so that the thickness of the semiconductor chip 6 can be larger.

In the above-described embodiments, two or more semiconductor chips can be mounted on each of the front surface 1a and the back surface 1b of the connection substrate 1. Note that each of the semiconductor chips 1 and 9 can be replaced by BGA packages, pin grid array (PGA) packages or wafer level chip size packages (WLCSPs).

Also, the connection substrates (interposer substrates) 1 and 9 can be rigid or flexible. Further, the electrode pads of the connection substrate 1 can be adhered to those of the connection substrate 9 by soldering or the like.

Further, passive elements can be mounted on the front surface 1a and/or the back surface 1b of the connection substrate 1.

Still, two or more openings can be provided in the connection substrate 9.

1. A semiconductor module comprising:
a first connection substrate having first and second surfaces opposite to each other;
at least one first semiconductor device mounted on the first surface of said first connection substrate;
a second connection substrate having at least one opening and adhered to the second surface of said first connection substrate;
at least one second semiconductor device mounted on the second surface of said first connection substrate through the opening of said second connection substrate; and
external electrodes formed on a surface of said second connection substrate opposite to said first connection substrate.

2. The semiconductor module as set forth in claim 1, wherein said external electrodes are electrically connected to said first and second semiconductor devices by interconnects of said first and second connection substrates.

3. The semiconductor module as set forth in claim 1, wherein a stand-off height defined by said second connection substrate and said external electrodes is larger than a height of said second semiconductor device with reference to the second surface of said first connection substrate.

4. The semiconductor module as set forth in claim 1, wherein said external electrodes are plain electrodes.

5. The semiconductor module as set forth in claim 1, wherein said external electrodes are protruded electrodes.

6. The semiconductor module as set forth in claim 1, further comprising a fine connection layer formed on the second surface of said first connection substrate.
